(19) United States
(12) Patent Application Publication
(10) Pub. No.: US 2026/0250551 A1
(43) Pub. Date: Aug. 27, 2026

(54) POLISHING AGENT FOR GALLIUM OXIDE SUBSTRATES, AND POLISHING METHOD

(71) Applicant: NISSAN CHEMICAL CORPORATION, Tokyo (JP)

(72) Inventors: Wataru OMORI, Funabashi-shi (JP); Shigeru MITSUI, Funabashi-shi (JP); Hibiki ISHIJIMA, Funabashi-shi (JP)

(73) Assignee: NISSAN CHEMICAL CORPORATION, Tokyo (JP)

(21) Appl. No.: 19/489,710

(22) PCT Filed: Jun. 7, 2024
(86) PCT No.: PCT/JP2024/020948

§ 371 Date: Dec. 3, 2025

(30) Foreign Application Priority Data
Jun. 8, 2023 (JP) 2023-094939

(51) Int. Cl. C09G 1/02; H10P 52/40

(52) U.S. Cl. CPC C09G 1/02; H10P 52/402

(57) ABSTRACT

A polishing composition for gallium oxide substrates and a polishing method, wherein the polishing composition contains silica particles, water, and polyvalent anions. The content of the polyvalent anions is 0.002 mole/liter or Jess in the polishing composition. The polyvalent anions include at least one kind of polyvalent anions selected from the group including sulfate ions, oxalate ions, citrate ions, and phosphate ions. The polishing composition for gallium oxide substrates additionally contains monovalent anions, and the content of the monovalent anions is 0.04 mole/liter or less in the polishing composition. The monovalent anions include at least one kind of monovalent anions selected from the group including nitrate ions, chloride ions, bromide ions, chlorate ions, bromide ions, acetate ions, formate ions, propionate ions, and butyrate ions. The polishing composition for gallium oxide substrates has a pH of 5.0 to 9.5 inclusive.

### TECHNICAL FIELD

The present invention relates to a polishing composition for a substrate made of an oxide such as gallium oxide.

### BACKGROUND ART

Compound semiconductor substrates made of silicon carbide, gallium nitride, gallium oxide or the like have been proposed as alternatives to silicon for power device substrates. Among these, gallium oxide is excellent in terms of the magnitude of the dielectric breakdown field strength and the cost of crystal growth. Compound semiconductor substrates are produced through a step including polishing. In the polishing step, there is a demand for improving productivity by increasing the polishing rate. Due to the strong cleavage tendency of gallium oxide, polishing with low friction resistance is also required to prevent breakage.

Patent Document 1 describes a polishing composition containing abrasive grains and water for gallium oxide. In examples, a polishing composition containing colloidal silica and deionized water is described. Many commercially available colloidal silicas contain anions, but this document does not specifically describe the presence, amount and type of the anions.

Patent Document 2 describes a polishing slurry for a gallium oxide substrate, the polishing slurry containing manganese dioxide particles and water.

### PRIOR ART DOCUMENTS

### Patent Documents

Patent Document 1: WO 2020/67057 A1
Patent Document 2: WO 2020/194944 A1

### SUMMARY OF THE INVENTION

### Problem to be Solved by the Invention

The present invention provides a polishing composition for polishing a gallium oxide substrate at a high polishing rate and a polishing method using the same.

### Means for Solving the Problem

The present invention provides, as a first aspect, a polishing composition for a gallium oxide substrate, the polishing composition containing silica particles, water, and a multivalent anion,
wherein a content of the multivalent anion in the polishing composition is 0.002 mol/L or less,
as a second aspect, the polishing composition according to the first aspect, wherein the multivalent anion is at least one multivalent anion selected from the group consisting of a sulfate ion, an oxalate ion, a citrate ion, and a phosphate ion,
as a third aspect, the polishing composition according to the first aspect, further containing a monovalent anion,
wherein a content of the monovalent anion in the polishing composition is 0.04 mol/L or less,
as a fourth aspect, the polishing composition according to the third aspect, wherein the monovalent anion is at least one monovalent anion selected from the group consisting of a nitrate ion, a chloride ion, a bromide ion, a chlorate ion, a bromate ion, an acetate ion, a formate ion, a propionate ion, and a butyrate ion,
as a fifth aspect, the polishing composition according to the third aspect, wherein the monovalent anion is at least one monovalent anion selected from the group consisting of a nitrate ion, a chloride ion, and an acetate ion,
as a sixth aspect, the polishing composition according to the first aspect, wherein a pH is 5.0 or more and 9.5 or less,
as a seventh aspect, the polishing composition according to the first aspect, wherein the silica particles have an average primary particle diameter of 5 to 100 nm,
as an eighth aspect, the polishing composition according to the first aspect, wherein the silica particles have an average secondary particle diameter of 30 nm to 150 nm,
as a ninth aspect, the polishing composition according to the first aspect, wherein the silica particles have a true density of 2.15 g/cm³ to 2.30 g/cm³,
as a tenth aspect, the polishing composition according to the first aspect, wherein the silica particles have a heat loss rate of 3.0% or less at 200° C. to 700° C.,
as an eleventh aspect, a method of producing the polishing composition according to any one of the first aspect to the tenth aspect, comprising the following steps (A) to (C):
step (A): a step of preparing an aqueous silica sol,
step (B): a step of bringing the aqueous silica sol obtained in the step (A) into contact with a strongly acidic ion exchange resin to obtain an acidic silica sol, and
step (C): a step of adjusting a pH of the acidic silica sol obtained in the step (B) using an alkali metal hydroxide or ammonia,
as a twelfth aspect, the method of producing the polishing composition according to the eleventh aspect, wherein the aqueous silica sol in the step (A) is produced by heating an activated silicic acid aqueous solution obtained by removing an alkali metal from an alkaline silicate aqueous solution,
as a thirteenth aspect, the method of producing the polishing composition according to the eleventh aspect, further comprising step (D):
step (D): a step of subjecting the polishing composition obtained in the step (C) to anion exchange,
as a fourteenth aspect, the method of producing the polishing composition according to the twelfth aspect, further comprising step (D):
step (D): a step of subjecting the polishing composition obtained in the step (C) to anion exchange,
as a fifteenth aspect, a method of producing the polishing composition according to any one of the first aspect to the tenth aspect, comprising the following steps (A), (B), (E), and (F):
step (A): a step of preparing an aqueous silica sol,
step (B): a step of bringing the aqueous silica sol obtained in the step (A) into contact with a strongly acidic ion exchange resin to obtain an acidic silica sol,
step (E): a step of subjecting the acidic silica sol obtained in the step (B) to anion exchange to obtain an alkaline silica sol, and
step (F): a step of adjusting a pH by adding a monobasic acid to the alkaline silica sol obtained in the step (E),
as a sixteenth aspect, the method of producing the polishing composition according to the fifteenth aspect, wherein the aqueous silica sol in the step (A) is produced by heating an activated silicic acid aqueous solution obtained by removing an alkali metal from an alkaline silicate aqueous solution,
as a seventeenth aspect, a method of polishing a gallium oxide substrate, comprising a step of polishing a gallium oxide substrate using the polishing composition according to any one of the first aspect to the tenth aspect, and
as an eighteenth aspect, the method of polishing a gallium oxide substrate according to the seventeenth aspect, wherein a polishing rate of the gallium oxide substrate is 3.0 μm/hour to 10.0 μm/hour.

### Effects of the Invention

In order to use gallium oxide for a power device substrate, precision polishing is required, and it is necessary to polish a workpiece to be polished without causing surface irregularities or defects at the atomic level in the compounds. In addition, in order to remove processing damage from prior steps, it is necessary to remove a predetermined thickness by polishing, and in order to shorten the processing time and improve the processing damage and productivity, it is required to perform polishing at a high polishing rate.

The silica particles dispersed in a solvent such as water are called a colloidal silica or also called a silica sol. It has been found in the present invention that, in a polishing composition containing water, silica particles and a multivalent anion, when an amount of specific multivalent anions is set to a certain amount or less, the polishing rate can be improved. In addition, it has been additionally found that, when an amount of specific monovalent anions is set to a certain amount or less, the polishing rate can be further improved.

Since multivalent anions and monovalent anions are often contained in colloidal silica, which is one of raw materials for a polishing composition, it is important to not only limit the content of an acid or salt added to adjust the pH of the polishing composition to a certain amount or less but also to use colloidal silica in which the content of anions is a certain amount or less or to reduce the amount of anions contained in the polishing composition to a certain level or below by a method of reducing the amount of anions contained in colloidal silica using an anion exchange resin or the like.

In the present invention, it has been found that specific multivalent anions and specific monovalent anions affect the polishing rate when polishing a gallium oxide substrate, and a high polishing rate is obtained by reducing the amount of these ions to a specific amount or less.

### MODES FOR CARRYING OUT THE INVENTION

The present invention relates to a polishing composition for a gallium oxide substrate, the polishing composition containing silica particles, water, and a multivalent anion, wherein a content of the multivalent anion in the polishing composition is 0.002 mol/L or less.

When silica particles are dispersed in water to form colloidal silica particles, water in the silica sol can be used in the polishing composition. In addition, water can be added to the silica sol and used as water in the polishing composition.

The polishing composition may contain silica particles in a range of 0.1% by mass to 50% by mass, and when it is used to polish a gallium oxide substrate, it can be used in a range of 1% by mass to 40% by mass, 5% by mass to 40% by mass, 5% by mass to 35% by mass, 5% by mass to 30% by mass, 10% by mass to 30% by mass, or 10% by mass to 25% by mass.

The multivalent anion may be, for example, at least one multivalent anion selected from the group consisting of a sulfate ion, an oxalate ion, a citrate ion, and a phosphate ion, and a sulfite ion, a carbonate ion, a phosphite ion, a borate ion, a malonate ion, and a tartrate ion.

It has been found that the multivalent anion such as a sulfate ion, an oxalate ion, a citrate ion, and a phosphate ion affects the polishing rate, and it is preferable to reduce the content of these multivalent anions in the polishing composition to a certain amount or less.

In order to obtain a high polishing rate, the content of the multivalent anion is preferably 0.002 mol/L or less. The upper limit value of the content of the multivalent anion may be in a range of 0.001 mol/L or less, 0.0008 mol/L or less, or 0.0006 mol/L or less. In addition, in order to obtain the stability of the silica sol, the content of the multivalent anion is preferably 0.000001 mol/L or more, and the lower limit value may be in a range of 0.000002 mol/L or more, 0.000003 mol/L or more, 0.000005 mol/L or more, 0.000007 mol/L or more, or 0.00001 mol/L or more.

In addition, preferably, the polishing composition contains a monovalent anion, and the content of the monovalent anion in the polishing composition is 0.04 mol/L or less.

The monovalent anion may be at least one monovalent anion selected from the group consisting of a nitrate ion, a chloride ion, a bromide ion, a chlorate ion, a bromate ion, an acetate ion, a formate ion, a propionate ion, a butyrate ion, a hydrogen sulfate ion, and a hydrogencarbonate ion. In addition, the monovalent anion may be at least one monovalent anion selected from the group consisting of a nitrate ion, a chloride ion, and an acetate ion.

The content of the monovalent anion is preferably 0.04 mol/L or less. In addition, in order to obtain a high polishing rate, the upper limit value of the content of the monovalent anion may be in a range of 0.03 mol/L or less, 0.02 mol/L or less, or 0.01 mol/L or less. In addition, in order to obtain the stability of the silica sol, the content of the monovalent anion may be in a range of 0.00001 mol/L or more, 0.0001 mol/L or more, 0.001 mol/L or more, or 0.002 mol/L or more.

In order to obtain a high polishing rate, the pH of the polishing composition is preferably 5.0 or more and 9.5 or less. The upper limit value of the pH may be in a range of 9.1, 9.0, 8.9, 8.8, or 8.7. In addition, the lower limit value of the pH may be in a range of 6.0, 6.2, 6.5, 6.8, or 7.0.

In order to obtain a high polishing rate, the average secondary particle diameter of the silica particles is preferably 30 nm or more. The lower limit value of the average secondary particle diameter may be in a range of 50 nm, 55 nm, or 60 nm. In addition, in order to obtain high polishing quality, the average secondary particle diameter of the silica particles is preferably less than 500 nm, and the upper limit value may be in a range of 300 nm, 200 nm, or 150 nm.

The average secondary particle diameter (D_{DLS}) of the silica particles can be determined from a particle size distribution of the silica particles measured by a dynamic light scattering method. The dynamic light scattering method is a method in which laser light is emitted to silica particles, and utilizing the fact that the scattering intensity of the obtained scattered light varies depending on the particle diameter of the silica particles, the particle size distribution is determined from the scattering intensity.

As a measurement device used to measure the particle size distribution of silica microparticles by the dynamic light scattering method, for example, a dynamic light scattering particle size distribution measurement device (commercially available from Malvern Panalytical) may be exemplified.

For the average primary particle diameter (D_{BET}) of the silica particles contained in the polishing composition of the present invention, the equivalent spherical particle diameter (nm) calculated from the surface area (or specific surface area) measured using a nitrogen gas adsorption method (BET method) can be measured as the average primary particle diameter.

Examples of devices used to measure the average primary particle diameter of silica particles using a nitrogen gas adsorption method (BET method) include a nitrogen gas adsorption method specific surface area measurement device (Monosorb commercially available from Quantachrome). Specifically, the value obtained from Formula ((D_{BET})=2720/S) for the specific surface area S (m²/g) measured by the nitrogen adsorption method using the above device and the equivalent spherical particle diameter is used as the average primary particle diameter (D_{BET}) measured by the BET method.

The content of the multivalent anion and the monovalent anion can be determined using ion chromatography.

In the present invention, additionally, the true density of the silica particles is preferably 2.15 g/cm³ or more. In order to obtain a high polishing rate, the lower limit value of the true density of the silica particles may be in a range of 2.16 g/cm³, 2.17 g/cm³, 2.18 g/cm³, or 2.19 g/cm³. In addition, the upper limit value may be in a range of 2.30 g/cm³, 2.28 g/cm³, 2.26 g/cm³, or 2.25 g/cm³.

The true density of the silica particles can be calculated using a measurement device that can measure the volume and mass of a corresponding amount of silica microparticles.

As the density measurement device used to measure the volume and mass of silica particles and calculate the true density from the measured values, for example, a dry automatic density measurement device (AccuPyc II TEC, commercially available from Micromeritics Instrument Corporation) may be exemplified. When this density meter is used, a predetermined amount of silica particles is put into the density meter, and the true density can be automatically measured.

In the present invention, additionally, the heat loss rate of the silica particles at 200° C. to 700° C. is preferably 3.0% or less. In order to obtain a high polishing rate, the upper limit value of the heat loss rate at 700° C. of the silica particles may be in a range of 2.0%, or 1.8%, and the lower limit value may be in a range of 0.6%, 0.8%, 1.0%, 1.2%, or 1.4%.

The heat loss rate of the silica particles can be measured through simultaneous thermogravimetry/differential thermal analysis (TGDTA).

As a measurement device used to measure the heat loss of silica particles through simultaneous thermogravimetry/differential thermal analysis, for example, a thermogravimetry/differential thermal analyzer (product name TG-DTA2000SA, commercially available from Bruker) may be exemplified.

For the measurement of the above true density and heat loss, silica particles (silica powder) extracted from the colloidal silica-dispersed solution contained in the polishing composition of the present invention can be used.

The silica particles (silica powder) are obtained by drying the colloidal silica. The drying method is not particularly limited. Specific examples of drying methods include hot air drying, blast drying, far-infrared heat drying, dehumidified air drying, natural drying (including sun drying), vacuum decompression drying, indirect heat drying, microwave heat drying, and vacuum freeze drying. The drying methods may be used alone or two or more thereof may be used in combination.

In addition, regarding the above drying step, as a pretreatment, the colloidal silica-dispersed solution is brought into contact with a strong acid type cation exchange resin and/or a strong base type anion exchange resin, or additionally with a weak acid type (carboxylic acid type) chelating resin and/or a weak base type (amine type) chelating resin, and thereby impurities such as metal cations can be removed from the colloidal silica-dispersed solution.

Here, an anion exchange resin converted to a hydroxyl group type by passing through a strong alkaline aqueous solution can be used, and examples of strong acid type cation exchange resins include Amberlite IR-120B, Amberjet 1020, and DOWEX MARATHONGH (product name, commercially available from Dow Chemical Company), DIAION SK104, DIAION PK208 (product name, commercially available from Mitsubishi Chemical Holdings), and Duolite C20J (product name, commercially available from Sumika Chemtex Co., Ltd.). Examples of strong base type anion exchange resins include Amberlite IRA400J, Amberlite IRA410J, and Amberjet 4400 (product name, commercially available from Dow Chemical Company), DIAION SA10A and DIAION SA20A (product name, commercially available from Mitsubishi Chemical Group Corporation), and Duolite UBA120 (product name, commercially available from Sumika Chemtex Co., Ltd.).

In the colloidal silica-dispersed solution, the SiO₂ solid content concentration is preferably 1% by mass to 50% by mass. In order to obtain a high polishing rate, the lower limit value of the SiO₂ solid content concentration may be in a range of 2% by mass, 5% by mass, 10% by mass, 15% by mass, or 20% by mass. In addition, in order to obtain the dispersion stability of particles, the upper limit value of the SiO₂ solid content concentration may be in a range of 40% by mass, 35% by mass, 30% by mass, or 25% by mass.

The smaller the shape parameter SF1 indicating the irregularity of the particle shape of the silica particles, the smaller the friction coefficient between the substrate and the polishing pad during polishing, and the lower the risk of cracking the substrate. In order to reduce the friction coefficient, the SF1 is preferably less than 1.60, and the upper limit value of SF1 may be a value of 1.53, 1.35, 1.30, 1.25, 1.22, 1.19, or 1.18.

The larger the shape parameter SF1_{>25} indicating the irregularity of the particle shape of the silica particles, the higher the polishing rate. In order to increase the polishing rate, the SF1_{>25} is preferably 1.16 or more, more preferably 1.23 or more, or 1.25 or more, still more preferably 1.30 or more, and yet more preferably 1.40 or more.

### (Measurement of Particle Diameter and Shape Factor Using Transmission Electron Microscope Image Analysis)

The shape factor SF1 is calculated as (area of a circle whose diameter is the maximum diameter of particles)/(projected area). That is,

$$\\ \begin{matrix}SF 1 = ( {DL}^{2} \times π / 4 ) / S & Formula ( 1 )\end{matrix}$$

DL is the maximum diameter (nm) of the particles and is the maximum length (nm) of the silica particles determined from a transmission electron microscope image, which is the maximum length between any two points on the periphery of the image. S is the projected area (nm²) of the silica particles. Specifically, transmission electron microscope images taken at a magnification of 10,000× or 30,000× are captured as electron data by an image analysis device (product name LUZEX, commercially available from Nireco) at a resolution of 146 dpi, and the projected area is defined as a value obtained by converting the number of pixels occupied by the silica particles into an area. For example, in the image at a magnification of 10,000×, the length of one side of one pixel is 17.8 nm and accordingly, the area per one pixel is converted to 319 nm². In addition, in the image at a magnification of 30,000×, the length of one side of one pixel is 6.0 nm, and accordingly, the area per one pixel is converted to 36 nm². For SF1, the maximum length DL and the projected area S are determined for each of 2,000 particles recognized by the image analysis device, the computation value of the above formula is calculated for each particle, and the average value thereof is used as SF1.

The shape factor SF1_{>25} is an average value of SF1 of particles having an equivalent circle diameter of 25 nm or more. That is, it can be determined by extracting only particles having an equivalent circle diameter of 25 nm or more, which is determined by image analysis of the transmission electron microscope image, and calculating the average value of SF1 of these particles. The equivalent circle diameter is the diameter (nm) of a perfect circle having the same projected area as the projected area S (nm²) of the silica particles. That is,

$$\\ \begin{matrix}D = 2 \times {( S / π )}^{0.5} & Formula ( 2 )\end{matrix}$$

As the colloidal silica-dispersed solution used in the polishing composition of the present invention, a silica sol produced by the alkoxide method can also be used, but a silica sol containing silica particles obtained by heating a silicic acid aqueous solution obtained by removing alkali metal ions from an alkaline silicate aqueous solution can be suitably used. In the silica sol produced by the alkoxide method, typically, the true density is less than 2.15 g/cm³, and the heat loss rate is 2.0% or more.

In order to adjust the pH, a pH adjusting agent can be added to the polishing composition of the present invention. The pH adjusting agent can be used to adjust the pH of an acidic aqueous silica sol to 5.0 to 9.5, or 6.0 to 9.5, or 6.0 to 9.1, or 6.0 to 9.0, or 6.0 to 8.9, or 6.5 to 8.8, or 7.0 to 8.7 by adding an alkaline substance.

The alkaline substance is an alkali metal hydroxide or ammonia, and sodium hydroxide, potassium hydroxide, or ammonia is preferably used, and can be added, for example, as a 0.1% by mass to 30% by mass aqueous solution.

In the polishing composition of the present invention, a water-soluble compound can be used. Examples of water-soluble compounds include monomers having a carboxylic acid group such as acrylic acid, methacrylic acid, and maleic acid, polymers thereof such as polyacrylic acid and polymethacrylic acid, and their salts such as ammonium polyacrylate, potassium polyacrylate, ammonium polymethacrylate, and potassium polymethacrylate. In addition, alginic acid, pectic acid, carboxymethylcellulose, polyaspartic acid, polyglutamic acid, polyamic acid, ammonium polyamic acid, polyvinylpyrrolidone, hydroxyethyl cellulose, glycerin, polyglycerin, polyvinyl alcohol, or carboxyl group- or sulfonic acid group-modified polyvinyl alcohol can be used.

The water-soluble compound can be contained in a proportion of 0.01% by mass to 10% by mass to the silica particles.

The silica particles used in the polishing composition of the present invention can be used as a silica sol.

The polishing composition is produced by a production method including the following steps (A) to (C), and can be produced by the method including
step (A): a step of preparing an aqueous silica sol,
step (B): a step of bringing the aqueous silica sol obtained in the step (A) into contact with a strongly acidic ion exchange resin to obtain an acidic silica sol, and
step (C): a step of adjusting the pH of the acidic silica sol obtained in the step (B) using an alkali metal hydroxide or ammonia.

The aqueous silica sol used in the step (A) can be obtained by, for example, any of the following methods (a1) to (a4).
step (a1): a silica sol obtained by subjecting a sodium silicate aqueous solution to ion exchange, removing alkali metal ions, and heating the obtained activated silicic acid aqueous solution,
step (a2): a silica sol obtained by hydrolysis of an alkoxysilane,
step (a3): a silica sol obtained by a method of wet-pulverizing silica powder in an aqueous medium, and
step (a4): a silica sol obtained by a method of dispersing silica powder obtained by combustion hydrolysis of silicon tetrachloride in a flame in an aqueous medium.

The method of the step (a1) can be broadly classified into a step (a-I) of obtaining activated silicic acid, a step (a-II) of heating and granulating activated silicic acid, and a step (a-III) of adjusting the concentration of the obtained silica sol.

The step (a-I) of obtaining activated silicic acid is a step in which an aqueous solution of an alkali metal silicate in which a water-soluble alkali metal silicate containing a metal oxide other than silica in a proportion of 300 ppm to 500,000 ppm to silica is dissolved at a concentration of 0.5% by mass to 10.0% by mass, or 1% by mass to 6% by mass as SiO₂ derived from the silicate is brought into contact with a hydrogen-type strongly acidic cation exchange resin, an aqueous solution of activated silicic acid with a SiO₂ concentration of 1% by mass to 6% by mass is produced, and this product solution is collected.

The step (a-II) of heating and granulating activated silicic acid includes, for example, the following steps (a-II-I) and (a-II-II).

Step (a-II-I): a step in which an aqueous solution containing at least one selected from the group consisting of alkali metal hydroxides, ammonia, and organic bases is added to the aqueous solution of the activated silicic acid collected in the step (a-I) as a stabilizing agent, and an aqueous solution of stabilized activated silicic acid having an SiO₂ concentration of 0.5% by mass to 10.0% by mass or 1% by mass to 6% by mass and a pH of 7 to 9 is produced or a step in which at least one selected from the group consisting of inorganic acids and organic acids is added as a stabilizing agent, and an aqueous solution of stabilized activated silicic acid having an SiO₂ concentration of 0.5% by mass to 10.0% by mass or 1% by mass to 6% by mass and a pH of 1 to 4 is produced.

Step (a-II-II): includes a step in which an aqueous solution containing a silicate compound obtained by adding an aqueous solution containing at least one selected from the group consisting of alkali metal hydroxides, ammonia, and organic bases to the aqueous solution of the activated silicic acid collected in the step (a-II-I) or an aqueous solution containing a silicate compound having a pH of 10 to 12.5 and an SiO₂ concentration of 0.1% by mass to 8% by mass obtained by concentrating or diluting the aqueous solution is produced.

In addition, a step in which the aqueous solution of the activated silicic acid obtained in the same manner as in the step (a-I) or (a-II-I) is supplied to the aqueous solution containing the silicate compound produced by the method while maintaining the temperature of the obtained mixed solution at 110° C. to lower than 150° C., or 110° C. to 145° C., or 110° C. to 140° C., or 110° C. to 135° C., or 110° C. to 130° C. with sufficient stirring for 1 to 30 hours until the pH of the mixed solution reaches 9 to 12 may be exemplified.

The step (a-III) of adjusting the concentration of the obtained silica sol is a step of concentrating the silica sol to 10% by mass to 50% by mass, but impurities can be removed before and after concentration. The step (a-III) is not essential but is performed as desired.

In the step (B), the aqueous silica sol can be brought into contact with a hydrogen-type strongly acidic cation exchange resin.

In the step (C), a step in which an alkali metal hydroxide or ammonia is added to the acidic silica sol obtained in the step (B) so that its pH reaches 6.0 to 9.5, 6.0 to 9.1, or 6.0 to 9.0, and a stable aqueous silica sol having an SiO₂ concentration of 10% by mass to 50% by mass or 30% by mass to 50% by mass, substantially free of a multivalent metal oxide other than silica, and having an average primary particle diameter of colloidal silica of 5 nm to 100 nm is produced may be exemplified. Such a silica sol can be contained in a range of 0.1% by mass to 50% by mass to prepare a polishing composition, but when used to polish a gallium oxide substrate by adding water to adjust the silica concentration, it can be used in a range of 0.1% by mass to 40% by mass, 1% by mass to 40% by mass, 5% by mass to 40% by mass, 5% by mass to 35% by mass, 5% by mass to 30% by mass, 10% by mass to 30% by mass, or 10% by mass to 25% by mass.

In addition, the polishing composition obtained in the step (C) can be subjected to an additional step (D) of performing anion exchange.

In addition, the polishing composition is produced by a production method including the following steps (A), (B), (E) and (F), and can be produced by the method including
step (A): a step of preparing an aqueous silica sol,
step (B): a step of bringing the aqueous silica sol obtained in the step (A) into contact with a strongly acidic ion exchange resin to obtain an acidic silica sol,
step (E): a step of subjecting the acidic silica sol obtained in the step (B) to anion exchange to obtain an alkaline silica sol, and
step (F): a step of adding a monobasic acid to the alkaline silica sol obtained in the step (E) to adjust the pH.

The present invention is a method of polishing a gallium oxide substrate including a step of polishing a gallium oxide substrate using the polishing composition.

In the polishing method, the polishing rate of the gallium oxide substrate can be 3.0 μm/hour to 10.0 μm/hour, or 4.0 μm/hour to 10.0 μm/hour.

### EXAMPLES

### (Average Secondary Particle Diameter Determined by Dynamic Light Scattering Method (DLS Method): Also Referred to as DLS Particle Diameter)

The average secondary particle diameter of the silica sol was determined by a dynamic light scattering method using a particle diameter measurement device Zetasizer Nano (commercially available from Malvern Panalytical). In addition, as the average secondary particle diameter, a Z-average particle diameter measured by a dynamic light scattering method was used.

### (Preparation of Heat-Dried Powder Sample)

75.0 g of pure water was added to 25.0 g of a silica sol (with a SiO₂ concentration of 40% by mass) to prepare a silica sol sample with a SiO₂ concentration adjusted to 10% by mass. Next, the obtained silica sol sample was treated with a hydrogen-type strongly acidic cation exchange resin Amberlite (product name) IR-120B and a hydroxyl group-type strongly basic anion exchange resin Amberlite (product name) IRA-410 to remove cations and anions as much as possible, and then heated and dried at 290° C. for 1 hour in an electric furnace (product name DX302, commercially available from Yamato Scientific Co., Ltd.) under an atmospheric atmosphere. The dried powder was thoroughly ground in an agate mortar to obtain a heat-dried powder sample.

### (Preparation of Freeze-Dried Powder Sample)

75.0 g of pure water was added to 25.0 g of a silica sol (with a SiO₂ concentration of 40% by mass) to prepare a silica sol sample with a SiO₂ concentration adjusted to 10% by mass. Next, the obtained silica sol sample was treated with a hydrogen-type strongly acidic cation exchange resin Amberlite (product name) IR-120B and a hydroxyl group-type strongly basic anion exchange resin Amberlite (product name) IRA-410 to remove cations and anions as much as possible, and then freeze-dried in a freeze-drying device (product name FDU-2100, commercially available from Tokyo Rikakikai Co., Ltd.) under a vacuum at a pressure of 5 Pa or less. The dried powder was thoroughly ground in an agate mortar to obtain a freeze-dried powder sample.

### (Specific Surface Area Diameter Determined by BET Method (Nitrogen Gas Adsorption Method): Also Referred to as Average Primary Particle Diameter Determined by BET Method or BET Particle Diameter)

The heat-dried powder of each silica sol was used as a measurement sample. The specific surface area value of the measurement sample was measured by a nitrogen adsorption method (BET method) using a specific surface area measurement device (product name Monosorb, commercially available from Quantachrome Instruments, Japan, Inc.), and the average primary particle diameter was determined from the obtained specific surface area value.

### (pH Measurement)

The pH indicates a value obtained from the pH measurement result, and was measured using a pH meter (product name Multi-Function Water Quality Meter MM-60R, and product name pH electrode GST-5741C, commercially available from DKK-TOA Corporation).

### (Measurement of True Density)

The heat-dried powder of each silica sol was used as a measurement sample. Using a dry automatic density measurement device (product name AccuPyc II TEC, commercially available from Micromeritics Instrument Corporation), the sample was introduced into a 1 cm³ cell to occupy 80% of its volume, and the true density thereof was measured.

### (Measurement of Heat Loss Rate)

Using a thermogravimetry/differential thermal analyzer (product name TG-DTA2000SA, commercially available from Bruker), the heat loss (%) was measured when the silica powder was heated from room temperature to 700° C. as follows.

A predetermined amount of the freeze-dried powder of each silica sol was introduced into a platinum container and heated in a nitrogen atmosphere at a heating rate of 10° C./min from room temperature to 700° C. Here, the flow rate of the nitrogen gas was 100 cc/min. The heat loss rate of the silica powder was calculated using the following formula from the values of a mass M1 of the sample when it reached 200° C. and a mass M2 of the sample when it reached 700° C.

$$\\ Heat loss rate ( \% ) = ( M 1 - M 2 ) \div M 1 \times 100$$

(Production of Activated Silicic Acid Aqueous Solution (a1))

A JIS No. 3 sodium silicate aqueous solution was prepared as a raw material: water-soluble alkali metal silicate. The main components of the sodium silicate aqueous solution other than water were SiO₂ (28.8% by mass) and Na₂O (9.47% by mass). 478 g of the sodium silicate aqueous solution was dissolved in 2,992 g of pure water to prepare 3,500 g of a sodium silicate aqueous solution. Next, the sodium silicate aqueous solution was passed through a column filled with the hydrogen-type strongly acidic cation exchange resin Amberlite IR-120B at a space velocity of 4.5 per hour, and 3,000 g of the obtained activated silicic acid aqueous solution (a1) was then collected in a container.

### Synthesis Example A

A reaction device including a stirrer, a heating device and the like provided in a pressure-resistant SUS container with an internal volume of 3 L was used. Using the activated silicic acid aqueous solution (a1) (3.5% by mass as SiO₂), 10% by mass of a potassium hydroxide aqueous solution, and pure water, the pH was adjusted to 11.1, the electric conductivity was adjusted to 14.8 mS/cm, and the liquid temperature in the container was then adjusted to 100° C. to 120° C. by heating. After the temperature in the container reached 100° C. to 120° C., while maintaining the temperature in the container at 100° C. to 120° C., the activated silicic acid aqueous solution (a1) (3.5% by mass as SiO₂) was additionally continuously supplied as a supply solution until the pH of the reaction solution reached 11.0, and the electric conductivity reached 3.6 mS/cm.

Subsequently, the obtained reaction solution was continuously heated at 100° C. to 120° C. for 1 hour to obtain a colloidal silica.

The obtained colloidal silica was concentrated at room temperature to a SiO₂ concentration of 40% by mass using a commercially available ultrafiltration device including a polysulfone tubular ultrafiltration membrane having a pore size of about 5 nm to obtain a colloidal silica A (a pH of 10.8, a sulfate ion concentration of 2 ppm, a D_{DLS} of 83 nm, a D_{BET} of 28 nm, an SF1 of 1.50, and an SF1_{>25} of 1.50).

### Synthesis Example B

A reaction device including a stirrer, a heating device and the like provided in a pressure-resistant SUS container with an internal volume of 3 L was used. Using a colloidal silica (product name ST-50T, commercially available from Nissan Chemical Corporation), 10% by mass of a potassium hydroxide aqueous solution, and pure water, the pH was adjusted to 11.2, the electric conductivity was adjusted to 3.7 mS/cm, and then the liquid temperature in the container was then adjusted to 100° C. to 120° C. by heating. After the temperature in the container reached 100° C. to 120° C., while maintaining the temperature in the container at 100° C. to 120° C., the activated silicic acid aqueous solution (a1) (3.5% by mass as SiO₂) was additionally continuously supplied as a supply solution until the pH of the reaction solution reached 10.5, and the electric conductivity reached 1.1 mS/cm.

Subsequently, the obtained reaction solution was continuously heated at 100° C. to 120° C. for 1 hour to obtain a colloidal silica.

Using a commercially available ultrafiltration device including a polysulfone tubular ultrafiltration membrane having a pore size of about 5 nm, the obtained colloidal silica was concentrated at room temperature to a SiO₂ concentration of 40% by mass to obtain a colloidal silica B (a pH of 10.5, a sulfate ion concentration of 46 ppm, a D_{DLS} of 52 nm, a D_{BET} of 33 nm, an SF1 of 1.20, and an SF1_{>25} of 1.20).

### Synthesis Example C

A reaction device including a stirrer, a heating device and the like provided in a pressure-resistant SUS container with an internal volume of 3 L was used. Using the colloidal silica B obtained in Synthesis Example B, 10% by mass of a potassium hydroxide aqueous solution, and pure water, the pH was adjusted to 11.4, the electric conductivity was adjusted to 8.9 mS/cm, and the liquid temperature in the container was then adjusted to 100° C. to 120° C. by heating. After the temperature in the container reached 100° C. to 120° C., while maintaining the temperature in the container at 100° C. to 120° C., the activated silicic acid aqueous solution (a1) (3.0% by mass to 4.0% by mass as SiO₂) and 10% by mass of the potassium hydroxide aqueous solution were additionally continuously supplied as supply solutions until the pH of the reaction solution reached 10.7, and the electric conductivity reached 1.7 mS/cm.

Subsequently, the obtained reaction solution was continuously heated at 100° C. to 120° C. for 1 hour to obtain a colloidal silica.

The obtained colloidal silica was concentrated at room temperature to a SiO₂ concentration of 40% by mass using a commercially available ultrafiltration device including a polysulfone tubular ultrafiltration membrane having a pore size of about 5 nm to obtain a colloidal silica C (a pH of 10.8, a sulfate ion concentration of 2 ppm, a D_{DLS} of 102 nm, a D_{BET} of 62 nm, an SF1 of 1.16, and an SF1_{>25} of 1.16).

### Synthesis Example D

A reaction device including a stirrer, a heating device and the like provided in a pressure-resistant SUS container with an internal volume of 3 L was used. Using the activated silicic acid aqueous solution (a1) (3.5% by mass as SiO₂), 10% by mass of a potassium hydroxide aqueous solution, and pure water, the pH was adjusted to 11.1, the electric conductivity wad adjusted to 11.3 mS/cm and the liquid temperature in the container was then adjusted to 100° C. to 120° C. by heating. After the temperature in the container reached 100° C. to 120° C., while maintaining the temperature in the container at 100° C. to 120° C., the activated silicic acid aqueous solution (a1) (3.5% by mass as SiO₂) was additionally continuously supplied as a supply solution until the pH of the reaction solution reached 11.0, and the electric conductivity reached 3.3 mS/cm.

Subsequently, the obtained reaction solution was continuously heated at 100° C. to 120° C. for 1 hour to obtain a colloidal silica.

Using a commercially available ultrafiltration device including a polysulfone tubular ultrafiltration membrane having a pore size of about 5 nm, the obtained colloidal silica was concentrated at room temperature to a SiO₂ concentration of 40% by mass to obtain a colloidal silica D (a pH of 10.8, a sulfate ion concentration of 6 ppm, a D_{DLS} of 45 nm, a D_{BET} of 19 nm, an SF1 of 1.51, and an SF1_{>25} of 1.64).

(Production of Activated Silicic Acid Aqueous Solution (a2))

An 8% sulfuric acid aqueous solution was added to the activated silicic acid aqueous solution (a1) (3.2% by mass as SiO₂) so that the content of sulfuric acid as a stabilizing agent was 0.313% by mass/SiO₂ to obtain a stabilized activated silicic acid aqueous solution (a2).

### Synthesis Example E

A reaction device including a stirrer, a heating device and the like provided in a pressure-resistant SUS container with an internal volume of 3 L was used. Using the stabilized activated silicic acid aqueous solution (a2) (3.2% by mass as SiO₂), 10% by mass of a potassium hydroxide aqueous solution, and pure water, the pH was adjusted to 11.0, the electric conductivity was adjusted to 10.1 mS/cm, and the liquid temperature in the container was then adjusted to 110° C. to 130° C. by heating. After the temperature in the container reached 100° C. to 130° C., while maintaining the temperature in the container at 110° C. to 130° C., the stabilized activated silicic acid aqueous solution (a2) (3.2% by mass as SiO₂) was additionally continuously supplied as a supply solution until the pH of the reaction solution reached 10.9 and the electric conductivity reached 3.5 mS/cm.

Subsequently, the obtained reaction solution was continuously heated at 110° C. to 130° C. for 2 hours to obtain a colloidal silica.

The obtained colloidal silica was concentrated at room temperature to a SiO₂ concentration of 40% by mass using a commercially available ultrafiltration device including a polysulfone tubular ultrafiltration membrane having a pore size of about 5 nm to obtain a colloidal silica E (a pH of 9.8, a sulfate ion concentration of 1,100 ppm, a D_{DLS} of 56 nm, a D_{BET} of 20 nm, an SF1 of 1.52, and an SF1_{>25} of 1.57).

### Experiment Example 1

The colloidal silica A prepared in Synthesis Example A was passed through a column filled with the hydrogen-type strongly acidic cation exchange resin Amberlite IR-120B at a space velocity of 4.5 per hour, and the obtained acidic colloidal silica A(+) was then collected in a container.

### Experiment Example 2

The colloidal silica B prepared in Synthesis Example B was passed through a column filled with the hydrogen-type strongly acidic cation exchange resin Amberlite IR-120B at a space velocity of 4.5 per hour, and the obtained acidic colloidal silica B(+) was then collected in a container. A hydroxyl group-type strongly basic anion exchange resin Amberlite (product name) IRA-410 was put into a container containing the acidic colloidal silica B(+) and stirred for 30 minutes, the IRA-410 was then removed using a #100 nylon mesh to obtain a colloidal silica B(+−) from which anions were removed.

### Experiment Example 3

The colloidal silica C prepared in Synthesis Example C was passed through a column filled with the hydrogen-type strongly acidic cation exchange resin Amberlite IR-120B at a space velocity of 4.5 per hour, and the obtained acidic colloidal silica C(+) was then collected in a container.

### Experiment Example 4

The colloidal silica D prepared in Synthesis Example D was passed through a column filled with the hydrogen-type strongly acidic cation exchange resin Amberlite IR-120B at a space velocity of 4.5 per hour, and the obtained acidic colloidal silica D(+) was then collected in a container.

### Experiment Example 5

The colloidal silica E prepared in Synthesis Example E was passed through a column filled with the hydrogen-type strongly acidic cation exchange resin Amberlite IR-120B at a space velocity of 4.5 per hour, and the obtained acidic colloidal silica E(+) was then collected in a container. A hydroxyl group-type strongly basic anion exchange resin Amberlite (product name) IRA-410 was put into a container containing the acidic colloidal silica E(+) and stirred for 30 minutes, the IRA-410 was then removed using a #100 nylon mesh to obtain a colloidal silica E(+−) from which anions were removed.

### Experiment Example 6

A ST-YL (product name Snowtex YL, a pH of 9.6, a silica concentration of 40% by mass, a sulfate ion concentration of 1,000 ppm, a D_{DLS} of 98 nm, a D_{BET} of 60 nm, an SF1 of 1.25, and an SF1_{>25} of 1.25, commercially available from Nissan Chemical Corporation) was passed through a column filled with the hydrogen-type strongly acidic cation exchange resin Amberlite IR-120B at a space velocity of 4.5 per hour, and the obtained acidic colloidal silica YL(+) was then collected in a container. A hydroxyl group-type strongly basic anion exchange resin Amberlite (product name) IRA-410 was put into a container containing the colloidal silica YL(+) and stirred for 30 minutes, and the IRA-410 was then removed using a #100 nylon mesh to obtain a colloidal silica YL(+−) from which anions were removed.

### Experiment Example 7

The colloidal silica C(+) prepared in Experiment Example 3 and a ST-O (product name Snowtex O, a pH of 2.6, a silica concentration of 20% by mass, a sulfate ion concentration of less than 1 ppm, a D_{DLS} of 19 nm, a D_{BET} of 12 nm, and an SF1 of 1.39, commercially available from Nissan Chemical Corporation) (colloidal silica O) were mixed in a ratio of 7:3 (silica solid content weight ratio) to obtain a mixture C(+)+O of the colloidal silica C(+) and the colloidal silica O.

### Example 1

The colloidal silica A(+) prepared in Experiment Example 1 and pure water were mixed and stirred to a silica concentration of 22% by mass, a potassium hydroxide aqueous solution in an amount that brought the pH to 8.4 was additionally added with stirring, pure water was additionally added to adjust the silica concentration to 20% by mass, and thereby a polishing composition of Example 1 was produced.

### Example 2

The colloidal silica A(+) prepared in Experiment Example 1 and pure water were mixed and stirred to a silica concentration of 22% by mass, sulfuric acid (a concentration of 8% by mass) was then added with stirring in an amount that brought the sulfate ion concentration to 0.28×10⁻³ M, a potassium hydroxide aqueous solution (a concentration of 10% by mass) was additionally added with stirring to adjust the pH to 8.3, pure water was additionally added to adjust the silica concentration to 20% by mass and the sulfate ion concentration to 0.25×10⁻³ M, and thereby a polishing composition of Example 1 was produced.

### Example 3

A polishing composition of Example 3 was produced in the same manner as in Example 2 except that the amount of sulfuric acid added was changed to achieve the concentration shown in Table 1.

### Example 4

A polishing composition of Example 4 was produced in the same manner as in Example 2 except that an oxalic acid aqueous solution (a concentration of 10% by mass) was added in place of sulfuric acid to achieve the concentration shown in Table 1.

For Example 5 to Example 8, each polishing composition was produced in the same manner as in Example 2 except that the type and amount of an acid (sulfuric acid (a concentration of 8% by mass), oxalic acid aqueous solution (a concentration of 10% by mass), hydrochloric acid (a concentration of 3.7% by mass) or acetic acid (a concentration of 6% by mass)) added in place of sulfuric acid were changed as shown in Table 2.

### Comparative Example 1

A polishing composition of Comparative Example 1 was produced in the same manner as in Example 2 except that the amount of sulfuric acid added was changed to achieve the concentration shown in Table 1.

### Comparative Example 2

The colloidal silica A prepared in Synthesis Example A and pure water were mixed and stirred to a silica concentration of 22% by mass, sulfuric acid (a concentration of 8% by mass) in an amount that brought the pH to 8.4 was then added with stirring, pure water was additionally added to adjust the silica concentration to 20% by mass, and thereby a polishing composition of Comparative Example 2 was produced.

For Comparative Example 3 to Comparative Example 5, each polishing composition was produced in the same manner as in Comparative Example 2 except that the type and amount of an acid (oxalic acid aqueous solution (a concentration of 10% by mass), citric acid aqueous solution (a concentration of 10% by mass), phosphoric acid (a concentration of 9.8% by mass)) added in place of sulfuric acid were as shown in Table 1.

For Example 9 to Example 11, each polishing composition was produced in the same manner as in Comparative Example 2 except that the type and amount of an acid added in place of sulfuric acid were as shown in Table 2.

For Example 12 to Example 15, each polishing composition was produced in the same manner as in Example 1 except that the amount of the potassium hydroxide aqueous solution added was changed to achieve the pH shown in Table 3.

### Example 16

The colloidal silica A(+) prepared in Experiment Example 1 and pure water were mixed and stirred to a silica concentration of 12% by mass, a potassium hydroxide aqueous solution was additionally added to a pH of 8.4 with stirring, pure water was additionally added to adjust the silica concentration to 10% by mass, and thereby a polishing composition of Example 1 was produced.

### Example 17

The colloidal silica A(+) prepared in Experiment Example 1 and pure water were mixed and stirred to a silica concentration of 32% by mass, nitric acid was then added to a nitrate ion concentration of 0.38×10⁻³ M with stirring, a potassium hydroxide aqueous solution was additionally added to a pH of 8.1 with stirring, pure water was additionally added to adjust the silica concentration to 30% by mass, and thereby a polishing composition of Example 17 was produced.

### Example 18

The colloidal silica E(+−) prepared in Experiment Example 5 and pure water were mixed and stirred to a silica concentration of 22% by mass, nitric acid was then added to a nitrate ion concentration of 0.38×10⁻³ M with stirring, a potassium hydroxide aqueous solution in an amount that brought the pH to 8.3 was additionally added with stirring, pure water was additionally added to adjust the silica concentration to 20% by mass and the nitrate ion concentration to 0.36×10⁻³ M, and thereby a polishing composition of Example 18 was produced.

### Example 19

The colloidal silica YL(+−) prepared in Experiment Example 6 and pure water were mixed and stirred to a silica concentration of 22% by mass, nitric acid was then added to nitrate ion concentration of 0.51×10⁻³ M with stirring, a potassium hydroxide aqueous solution was additionally added to a pH of 8.6 with stirring, pure water was additionally added to adjust the silica concentration to 20% by mass and the nitrate ion concentration to 0.46×10⁻³ M, and thereby a polishing composition of Example 19 was produced.

### Example 20

The colloidal silica B(+−) prepared in Experiment Example 2 and pure water were mixed and stirred to a silica concentration of 22% by mass, nitric acid was then added to a nitrate ion concentration of 0.20×10⁻³ M with stirring, a potassium hydroxide aqueous solution was additionally added to a pH of 8.4 with stirring, pure water was additionally added to adjust the silica concentration to 20% by mass and the nitrate ion concentration to 0.18×10⁻³ M, and thereby a polishing composition of Example 19 was produced.

For Example 21 to Example 24, each polishing composition was produced in the same manner as in Example 1 except that the type of the colloidal silica and the pH after the potassium hydroxide aqueous solution was added were changed as shown in Table 4.

Here, a trace amount of sulfate ions (0.01×10⁻³ M) contained in Example 1 and Examples 5 to 23 was entirely derived from the raw material colloidal silica A, and was not additionally added. Here, in Table 4, PL-3 indicates a commercially available alkoxide-method colloidal silica (product name PL-3, commercially available from Fuso Chemical Co., Ltd.), and C(+)+O indicates a mixture of colloidal silica C(+) and colloidal silica O.

TABLE 1

| | | | | Anion \textcircled{1} | | Anion \textcircled{2} | |
|---|---|---|---|---|---|---|---|
| | Colloidal | SiO₂ | | | Concentration | | Concentration |
| | silica | (%) | pH | Type | (×10⁻³ M) | Type | (×10⁻³ M) |
| Example 1 | A(+) | 20 | 8.4 | SO₄²⁻ | 0.01 | — | — |
| Example 2 | A(+) | 20 | 8.3 | SO₄²⁻ | 0.25 | — | — |
| Example 3 | A(+) | 20 | 8.4 | SO₄²⁻ | 0.60 | — | — |
| Example 4 | A(+) | 20 | 8.4 | oxalic acid | 0.18 | SO₄²⁻ | 0.01 |
| Comparative | A(+) | 20 | 8.3 | SO₄²⁻ | 2.35 | — | — |
| Example 1 | | | | | | | |
| Comparative | A | 20 | 8.4 | SO₄²⁻ | 22.13 | — | — |
| Example 2 | | | | | | | |
| Comparative | A | 20 | 8.4 | oxalic acid | 21.96 | SO₄²⁻ | 0.01 |
| Example 3 | | | | | | | |
| Comparative | A | 20 | 8.4 | citric acid | 14.65 | SO₄²⁻ | 0.01 |
| Example 4 | | | | | | | |
| Comparative | A | 20 | 8 | phosphoric acid | 23.01 | SO₄²⁻ | 0.01 |
| Example 5 | | | | | | | |

TABLE 2

| | | | | Anion \textcircled{1} | | Anion\textcircled{2} | |
|---|---|---|---|---|---|---|---|
| | Colloidal | SiO₂ | | | Concentration | | Concentration |
| | silica | (%) | pH | Type | (×10⁻³ M) | Type | (×10⁻³ M) |
| Example 5 | A(+) | 20 | 8.2 | NO₃⁻ | 4.56 | SO₄²⁻ | 0.01 |
| Example 6 | A(+) | 20 | 8.2 | NO₃⁻ | 9.11 | SO₄²⁻ | 0.01 |
| Example 7 | A(+) | 20 | 8.3 | Cl⁻ | 3.18 | SO₄²⁻ | 0.01 |
| Example 8 | A(+) | 20 | 8.4 | acetic acid | 3.83 | SO₄²⁻ | 0.01 |
| Example 9 | A | 20 | 8.3 | NO₃⁻ | 44.07 | SO₄²⁻ | 0.01 |
| Example 10 | A | 20 | 8.4 | Cl⁻ | 42.34 | SO₄²⁻ | 0.01 |
| Example 11 | A | 20 | 8.4 | acetic acid | 43.67 | SO₄²⁻ | 0.01 |

TABLE 3

| | | | | Anion \textcircled{1} | | Anion \textcircled{2} | |
|---|---|---|---|---|---|---|---|
| | Colloidal | SiO₂ | | | Concentration | | Concentration |
| | silica | (%) | pH | Type | (×10⁻³ M) | Type | (×10⁻³ M) |
| Example 12 | A(+) | 20 | 6.3 | SO₄²⁻ | 0.01 | — | — |
| Example 13 | A(+) | 20 | 7.5 | SO₄²⁻ | 0.01 | — | — |
| Example 1 | A(+) | 20 | 8.4 | SO₄²⁻ | 0.01 | — | — |
| Example 14 | A(+) | 20 | 5.0 | SO₄²⁻ | 0.01 | — | — |
| Example 15 | A(+) | 20 | 9.4 | SO₄²⁻ | 0.01 | — | — |
| Example 16 | A(+) | 10 | 8.3 | SO₄²⁻ | 0.01 | — | — |
| Example 17 | A(+) | 30 | 8.1 | SO₄²⁻ | 0.02 | NO₃⁻ | 0.36 |

TABLE 4

| | | | | Anion \textcircled{1} | | Anion \textcircled{2} | |
|---|---|---|---|---|---|---|---|
| | Colloidal | SiO₂ | | | Concentration | | Concentration |
| | silica | (%) | pH | Type | (×10⁻³ M) | Type | (×10⁻³ M) |
| Example 18 | E(+−) | 20 | 8.3 | SO₄²⁻ | <0.01 | NO₃⁻ | 0.36 |
| Example 1 | A(+) | 20 | 8.4 | SO₄²⁻ | 0.01 | — | — |
| Example 19 | YL(+−) | 20 | 8.6 | SO₄²⁻ | <0.01 | NO₃⁻ | 0.46 |
| Example 20 | B(+−) | 20 | 8.4 | SO₄²⁻ | 0.07 | NO₃⁻ | 0.18 |
| Example 21 | C(+) | 20 | 8.5 | SO₄²⁻ | 0.04 | — | — |
| Example 22 | C(+) + O | 20 | 8.1 | SO₄²⁻ | 0.02 | — | — |
| Example 23 | D(+) | 20 | 8.3 | SO₄²⁻ | 0.02 | — | — |
| Example 24 | PL-3 | 20 | 8.3 | — | — | — | — |

TABLE 5

| | | | | | True | |
|---|---|---|---|---|---|---|
| | D_{DLS} | D_{BET} | | | density | Heat loss |
| | (nm) | (nm) | SF1 | SF1_{>25} | (g/cm³) | rate (%) |
| Example 18 | 56 | 20 | 1.52 | 1.57 | 2.22 | |
| Example 1 | 83 | 28 | 1.50 | 1.50 | 2.23 | 1.64 |
| Example 19 | 96 | 61 | 1.25 | 1.25 | | |
| Example 20 | 52 | 33 | 1.20 | 1.20 | 2.21 | |
| Example 21 | 102 | 62 | 1.16 | 1.16 | 2.20 | |
| Example 22 | 97 | 28 | 1.39 | 1.21 | | |
| Example 23 | 45 | 19 | 1.51 | 1.64 | | |
| Example 24 | 67 | 35 | 1.47 | 1.47 | 2.11 | 2.83 |

A commercially available gallium oxide single crystal substrate was polished by the following method.
Polishing machine: TriboLabCMP (product name, commercially available from Bruker)
Pressure: 250 g/cm²
Plate rotation speed: 80 rpm
Substrate rotation speed: 80 rpm
Polishing pad: SUBA600 (product name, commercially available from Nitta Dupont Inc.)
The amount of the polishing composition used: 0.9 L
Polishing composition supply rate: 100 mL/min (circulation use)
Polishing time: 1 hour
Substrate: β-gallium oxide, a diameter of 2 inch
Number of substrates: 1

### (Method of Measuring Polishing Rate)

The polishing rate was calculated from the weight loss before and after the substrate was polished, assuming a substrate density of 5.88 g/cm³.

In the following Tables 6 to 9, the polishing rate (μm/h) indicates micrometers/hour.

TABLE 6

| | Polishing | Friction |
|---|---|---|
| | rate (μm/h) | coefficient |
| Example 1 | 4.9 | 0.47 |
| Example 2 | 4.0 | 0.51 |
| Example 3 | 3.7 | 0.51 |
| Example 4 | 4.1 | 0.53 |
| Comparative Example 1 | 2.9 | 0.54 |
| Comparative Example 2 | 1.9 | 0.57 |
| Comparative Example 3 | 2.2 | 0.60 |
| Comparative Example 4 | 0.2 | 0.58 |
| Comparative Example 5 | 0.8 | 0.65 |

TABLE 7

| | Polishing | Friction |
|---|---|---|
| | rate (μm/h) | coefficient |
| Example 5 | 4.4 | 0.48 |
| Example 6 | 4.2 | 0.47 |
| Example 7 | 4.4 | 0.49 |
| Example 8 | 4.1 | 0.50 |
| Example 9 | 3.8 | 0.49 |
| Example 10 | 3.7 | 0.48 |
| Example 11 | 3.5 | 0.49 |

TABLE 8

| | Polishing | Friction |
|---|---|---|
| | rate (μm/h) | coefficient |
| Example 12 | 4.1 | 0.43 |
| Example 13 | 4.7 | 0.43 |
| Example 1 | 4.9 | 0.47 |
| Example 14 | 3.5 | 0.48 |
| Example 15 | 3.5 | 0.52 |
| Example 16 | 4.0 | 0.44 |
| Example 17 | 4.8 | 0.51 |

TABLE 9

| | Polishing | Friction |
|---|---|---|
| | rate (μm/h) | coefficient |
| Example 18 | 4.1 | 0.47 |
| Example 1 | 4.9 | 0.47 |
| Example 19 | 4.6 | 0.32 |
| Example 20 | 3.9 | 0.33 |
| Example 21 | 4.0 | 0.26 |
| Example 22 | 3.9 | 0.47 |
| Example 23 | 3.5 | 0.48 |
| Example 24 | 3.2 | 0.39 |

As shown in the examples, in the polishing composition for a gallium oxide substrate, the polishing composition containing silica particles and water, when the content of the multivalent anion is set to 0.002 mol/L or less, as shown in the polishing rates in Tables 6 to 9, high polishing rates can be obtained.

In addition, a higher polishing rate can be obtained by balancing other parameters.

When the content of the multivalent anion is set to 0.002 mol/L or less and the content of the monovalent anion is additionally set to 0.04 mol/L or less, as shown in the polishing rates in Table 7, even higher polishing rates can be obtained.

When the content of the multivalent anion is set to 0.002 mol/L or less and the pH is additionally set to 6.0 to 9.1, as shown in the polishing rates in Table 8, even higher polishing rates can be obtained.

In addition, it has been found that, when the true density of the silica particles, the heat loss rate at 200° C. to 700° C., the average secondary particle diameter, SF1_{>25} and SF1 also satisfy certain conditions, the polishing rate can be increased.

For example, in the polishing composition shown in Example 18 to Example 24, when the true density of the silica particles is additionally set to 2.15 g/cm³ or more, as shown in the polishing rates in Table 9, even higher polishing rates can be obtained.

When the heat loss rate of the silica particles at 200° C. to 700° C. is additionally set to 2.0% or less, as shown in the polishing rates in Table 9, even higher polishing rates can be obtained.

In addition, when the average secondary particle diameter of the silica particles is set to 50 nm or more, as shown in the polishing rates in Table 9, an even higher high polishing rate can be obtained.

When the SF1_{>25} of the silica particles is additionally set to 1.23 or more, as shown in the polishing rates in Table 9, even higher polishing rates can be obtained. In addition, when the SF1 of the silica particles is set to less than 1.35, as shown in the friction coefficients in Table 9, the friction resistance can be kept low.

### INDUSTRIAL APPLICABILITY

It is possible to provide a polishing composition for polishing a gallium oxide substrate at a high polishing rate and a polishing method using the same.

1. A polishing composition for a gallium oxide substrate, the polishing composition containing silica particles, water, and a multivalent anion,
wherein a content of the multivalent anion in the polishing composition is 0.002 mol/L or less.

2. The polishing composition according to claim 1, wherein the multivalent anion is at least one multivalent anion selected from the group consisting of a sulfate ion, an oxalate ion, a citrate ion, and a phosphate ion.

3. The polishing composition according to claim 1, further containing a monovalent anion,
wherein a content of the monovalent anion in the polishing composition is 0.04 mol/L or less.

4. The polishing composition according to claim 3, wherein the monovalent anion is at least one monovalent anion selected from the group consisting of a nitrate ion, a chloride ion, a bromide ion, a chlorate ion, a bromate ion, an acetate ion, a formate ion, a propionate ion, and a butyrate ion.

5. The polishing composition according to claim 3, wherein the monovalent anion is at least one monovalent anion selected from the group consisting of a nitrate ion, a chloride ion, and an acetate ion.

6. The polishing composition according to claim 1, wherein a pH is 5.0 or more and 9.5 or less.

7. The polishing composition according to claim 1, wherein the silica particles have an average primary particle diameter of 5 to 100 nm.

8. The polishing composition according to claim 1, wherein the silica particles have an average secondary particle diameter of 30 nm to 150 nm.

9. The polishing composition according to claim 1, wherein the silica particles have a true density of 2.15 g/cm³ to 2.30 g/cm³.

10. The polishing composition according to claim 1, wherein the silica particles have a heat loss rate of 3.0% or less at 200° C. to 700° C.

11. A method of producing the polishing composition according to claim 1, comprising the following steps (A) to (C):
step (A): a step of preparing an aqueous silica sol,
step (B): a step of bringing the aqueous silica sol obtained in the step (A) into contact with a strongly acidic ion exchange resin to obtain an acidic silica sol, and
step (C): a step of adjusting a pH of the acidic silica sol obtained in the step (B) using an alkali metal hydroxide or ammonia.

12. The method of producing the polishing composition according to claim 11, wherein the aqueous silica sol in the step (A) is produced by heating an activated silicic acid aqueous solution obtained by removing an alkali metal from an alkaline silicate aqueous solution.

13. The method of producing the polishing composition according to claim 11, further comprising step (D):
step (D): a step of subjecting the polishing composition obtained in the step (C) to anion exchange.

14. The method of producing the polishing composition according to claim 12, further comprising step (D):
step (D): a step of subjecting the polishing composition obtained in the step (C) to anion exchange.

15. A method of producing the polishing composition according to claim 1, comprising the following steps (A), (B), (E), and (F):
step (A): a step of preparing an aqueous silica sol,
step (B): a step of bringing the aqueous silica sol obtained in the step (A) into contact with a strongly acidic ion exchange resin to obtain an acidic silica sol,
step (E): a step of subjecting the acidic silica sol obtained in the step (B) to anion exchange to obtain an alkaline silica sol, and
step (F): a step of adjusting a pH by adding a monobasic acid to the alkaline silica sol obtained in the step (E).

16. The method of producing the polishing composition according to claim 15, wherein the aqueous silica sol in the step (A) is produced by heating an activated silicic acid aqueous solution obtained by removing an alkali metal from an alkaline silicate aqueous solution.

17. A method of polishing a gallium oxide substrate, comprising a step of polishing a gallium oxide substrate using the polishing composition according to claim 1.

18. The method of polishing a gallium oxide substrate according to claim 17, wherein a polishing rate of the gallium oxide substrate is 3.0 μm/hour to 10.0 μm/hour.
